(19) United States
(12) Patent Application Publication
(10) Pub. No.: US 2013/0088835 A1
(43) Pub. Date: Apr. 11, 2013

(54) ACTIVE AIR-COOLING DEVICE FOR ELECTRONIC CIRCUITS

(71) Applicant: Todd R. Salamon, New Providence, NJ (US)

(72) Inventor: Todd R. Salamon, New Providence, NJ (US)

(73) Assignee: Alcatel-Lucent., Murray Hill, NJ (US)

(21) Appl. No.: 13/329,047

(22) Filed: Dec. 16, 2011

Related U.S. Application Data
(60) Provisional application No. 61/545,999, filed on Oct. 11, 2011.

(51) Int. Cl. H05K 7/20; F24F 7/007

(52) U.S. Cl. 361/695; 454/251

(57) ABSTRACT

A device comprising a casing and a motorized air-mover. The casing encloses an air-inlet duct, air-outlet duct and a cavity located between the air-inlet duct and the air-outlet duct and in air-flow communication with the air-inlet duct and the air-outlet duct. The motorized air-mover is located in the cavity, the motorized air-mover configured to move air from the air-inlet duct to the air-outlet duct, wherein there is a gap between an outer-surface of the motorized air-mover and an interior wall of casing defining the cavity.

### CROSS-REFERENCE TO RELATED APPLICATIONS

The present application claims the benefit to the previously filed U.S. Provisional Patent Application No. 61/545,999 of the same title, filed Oct. 11, 2011 by Todd R. Salamon, and which is incorporated herein by reference in its entirety.

### TECHNICAL FIELD

The present invention is directed, in general, to a cooling device and, more specifically, to a device for cooling electronic circuits.

### BACKGROUND OF THE INVENTION

Components on electronic circuit boards generate heat which must be dissipated; otherwise the components operate at too high a temperature, which can lead to premature failure and diminished long-term reliability of the heat generating component or other components on the electronic circuit board.

### SUMMARY

One embodiment includes a device, comprising a casing and a motorized air-mover. The casing encloses an air-inlet duct, air-outlet duct and a cavity located between the air-inlet duct and the air-outlet duct and in air-flow communication with the air-inlet duct and the air-outlet duct. The motorized air-mover is located in the cavity, the motorized air-mover configured to move air from the air-inlet duct to the air-outlet duct, wherein there is a gap between an outer-surface of the motorized air-mover and an interior wall of casing defining the cavity.

In some embodiments, the gap is configured such that a distance separating the outer-surface of the motorized air-mover and the interior wall is a gap value in a range of 10 to 1000 microns. In some embodiments, the casing is configured such that a direction of air expelled from the air-outlet duct is in substantially a same direction of outside air-flow taken into the air-inlet duct. In some embodiments, one or both of the air-inlet duct or cavity are surrounded by a high-thermal conductivity material. In some embodiments, the high-thermal conductivity material is configured as a vapor chamber or a thermal siphon. In some embodiments, the high-thermal conductivity material includes channels that allow the circulation of a single or two-phase fluid there-through. In some embodiments, the motorized air-mover is configured as an impeller. In some embodiments, blades of the impeller are configured to increase in height from a central location of the impeller to a perimeter of the impeller. In some embodiments, the motorized air-mover is conically-shaped. In some embodiments, the motorized air-mover is cylindrically shaped. In some embodiments, the cavity is configured to have a shape that matches at least a portion of the exterior shape of the motorized air-mover such that the gap is present on all sides of the motorized air-mover except for sides that are facing the air-inlet duct or the air-outlet duct.

Another embodiment is an apparatus. The apparatus comprises an electronic circuit board having one or more heat sources thereon. The apparatus also comprises one or more devices located proximate to one of the heat sources, each of the devices including the above-described casing and motorized air-mover.

In some embodiments, each of a plurality of the devices is configured to expel air from the air-outlet duct in substantially a same direction as each other. In some embodiments, each of the devices is configured to intake air from the air-inlet duct substantially a same direction as each other. In some embodiments, for each of the one or more devices a direction of air expelled from the air-outlet duct is substantially the same as a direction of outside air-flow taken into the air-inlet duct. In some embodiments, the heat source includes one or more active devices. In some embodiments, the heat source includes one or more passive devices. In some embodiments, the gap is configured such that a distance separating the outer-surface of the motorized air-mover and the interior wall is a gap value in a range of 10 to 1000 microns.

### BRIEF DESCRIPTION OF THE DRAWINGS

The embodiments of the disclosure are best understood from the following detailed description, when read with the accompanying FIGURES. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1 presents a cross-sectional view of an example device of the present disclosure;

FIG. 2 presents a cross-sectional view of another example device of the present disclosure;

FIG. 3 presents a perspective view of an example air-mover of the present disclosure, such as the air-mover of any of the devices depicted in FIGS. 1-2; and

FIG. 4 presented a plan view of an example electronics apparatus of the present disclosure which can include any of the example devices and component parts depicted in FIGS. 1-3.

### DETAILED DESCRIPTION

The description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Moreover, all statements herein reciting principles, aspects, and embodiments of the invention, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

Some embodiments of the present disclosure improve the dissipation of heat from heat generating electronic components (e.g., heat sources) by combing a casing having internal duct-work and a motorized air-mover, the device situated in close proximity to the heat source on an electronic circuit board.

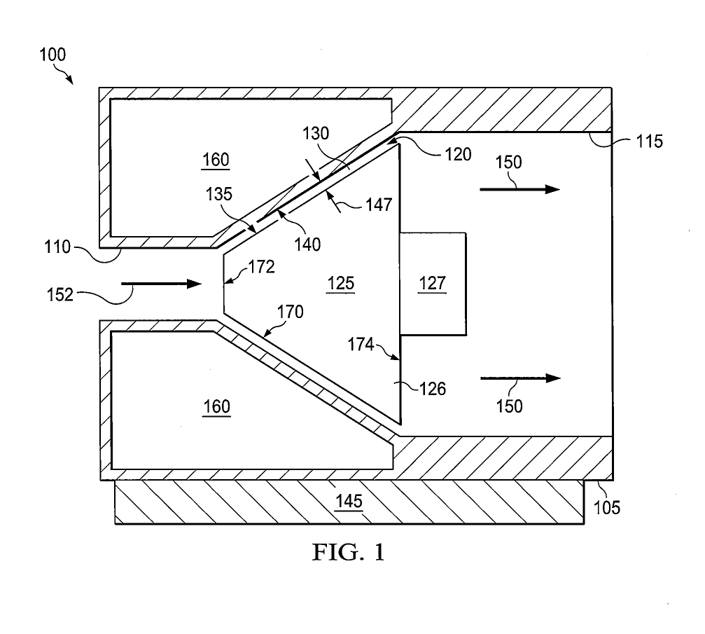

One embodiment of the disclosure is a device. FIG. 1 presents a cross-sectional view of an example device 100 of the present disclosure. The device 100 comprises a casing 105 (e.g., a metal casing) enclosing an air-inlet duct 110, air-outlet duct 115 and a cavity 120 located between the air-inlet duct 110 and the air-outlet duct 115 and in air-flow communication with the air-inlet duct 110 and the air-outlet duct 115. The device 100 also comprises a motorized air-mover 125 (e.g., including a fan portion 126, e.g., an impeller or other air moving structure, and motor portion 127) located in the cavity 120, the motorized air-mover 125 configured to move air from the air-inlet duct 110 to the air-outlet duct 115. There is a gap 130 (e.g., a thin gap) between an outer-surface 135 of the motorized air-mover 125 and an interior wall 140 of the casing 105 defining the cavity 120.

In some embodiments, the cavity 105 is configured to provide the gap 130 such that that there is efficient heat transfer from a heat source 145 through air in the gap 130 to the air circulating through the motorized air-mover 125. Too large an air gap 130 may undesirably reduce heat transfer. For example, in some embodiments, a distance 147 (e.g., a gap value) separating the outer-surface 135 of the motorized air-mover 125 and the interior wall 140 is less than about 1000 microns, in some cases preferably a value in a range of 100 to 1000 microns, and, in some cases, in a range of 10 to 1000 microns. In some cases a gap 130 of greater than 1000 microns is considered too large. In some embodiments, the gap 130 distance 147 remains substantially uniform (e.g. within about ±20 percent and in some case less than about ±10 percent with respect to a side 170 opposing the wall 140) when the motorized air-mover 125 is actively moving air (e.g., the motor is rotating).

In some embodiments, the casing 105 and its interior duct work (e.g., defining the inlet and outlet ducts 110, 115) can be configured to direct air flow through the device 100 in a desired direction to facilitate heat dissipation from the heat source 145. For instance, as illustrated in FIG. 1 in some cases, the casing 105 is configured such that a direction 150 of air expelled from the air-outlet duct 115 is in substantially a same direction 152 as outside air-flow taken into the air-inlet duct 110. For instance, in certain cases, such as when dissipating heat from heat sources on circuit packs, it is desirable to maintain air flow in a particular direction. In some cases, this can be advantageous over certain air-mover designs (e.g., impellers having uniform-height blades) having orthogonal inlet and outlet air flow directions because heat removal is more efficiently removed or to meet geometric space constraints of the shape of the casing 105.

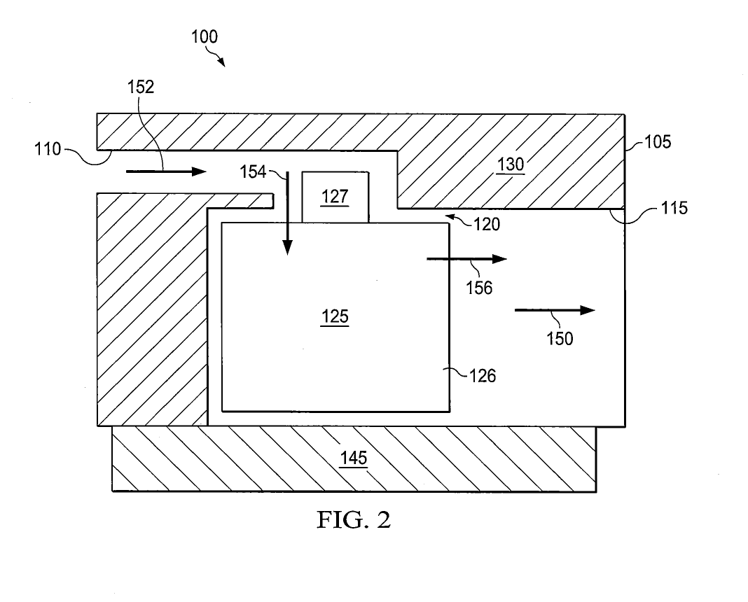

However, in other cases such as illustrated in FIG. 2, the air-inlet duct 110 can be configured to direct air within the casing to an air mover that is configured to receive air and expel air in orthogonal directions (e.g., in-flow direction 154 and out-flow direction 156, FIG. 2), but still have the direction 150 of air expelled from the air-outlet duct 115 in substantially the same direction 152 as the air-flow taken into the air-inlet duct 110.

As further illustrated in FIG. 1 in some embodiments, to improve heat transfer efficiency, heat from the heat source 145 may also be transferred through a portion of the casing 105 to the gap 130. For instance, in some cases, the cavity 140 can be surrounded by a high-thermal conductivity material 160. For instance, in some cases, one of both of the air-inlet duct 110 or the cavity 140 can be surrounded by the high-thermal conductivity material 160. The term high-thermal conductivity material refers to a material or combination of materials having a thermal conductivity of at least about 200 W/mK, and in some case at least about 500 W/mK, and in some cases at least about 1500 W/mK, and in some cases at least about 10000 W/mk. In some cases, the air-inlet duct 110 or cavity 140 can be surrounded by a high-thermal conductivity material 160 that is a solid metal or metal alloy (e.g., aluminum or copper), and having, e.g., a thermal conductivity at least about 200 W/mK. In some cases, the high-thermal conductivity material 160 may be part of the casing 105. In some cases the high-thermal conductivity material 160 is configured as a vapor chamber or a thermal siphon having a thermal conductivity, e.g., of at least about 1500 W/mK. In other embodiments, the material 160 can include channels that allow the circulation of a refrigerant fluid (e.g., a single or two-phase fluid) there-through. For instance, the channel can be configured to allow the recirculation (e.g., via a pump) of a fluid, e.g., a single-phase liquid in some cases, or, a two-phase fluid in other cases, to facilitate heat transport from the heat source 145 to the surface 140.

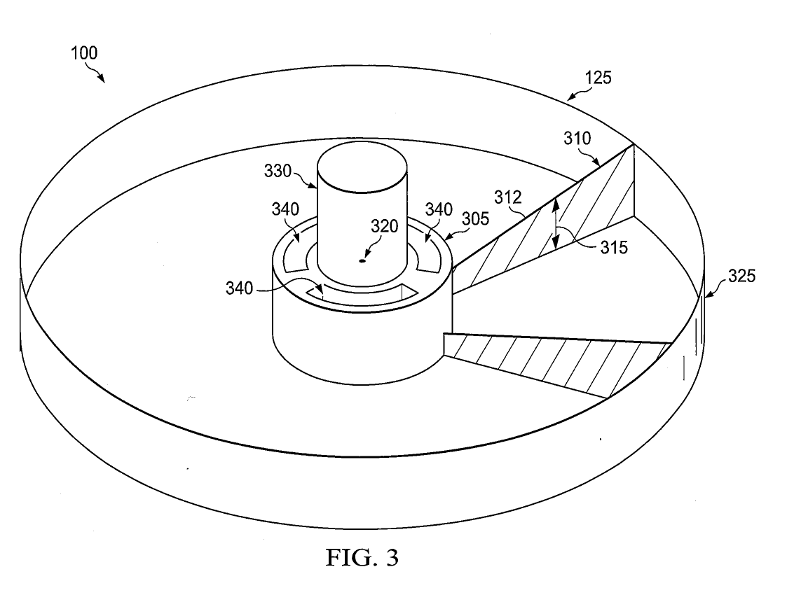

In some embodiments, as illustrated in FIG. 3, to facilitate efficient air flow in a compact space, the motorized air-mover 125 is configured as an impeller. Some embodiments of the impeller 125 can have central wheel 305 with uniformly-shaped blades 310 coupled thereto the blades projecting out radially (or axially) from the central wheel 305.

For clarity only two of a plurality of blades 310 are shown in FIG. 3. In some cases the blades 310 have straight edges 312, as depicted, but in other cases, the blades 310 can have curved edges 312. In some embodiments, the blades 310 of the impeller 125 are configured to increase in height 315 from a central location 320 (e.g., a center axis) of the impeller 125 (e.g., central to the wheel 305) to a perimeter 325 of the impeller 125. Such a configuration can facilitate having the same inflow direction 156 and out-flow direction of air transfer through the impeller 125. This, in turn, can mitigate the need to create a bend in the air-inlet duct 110 or air-outlet duct 115, e.g., to make the direction 150 of air expelled from the air-outlet duct 115 to be in substantially the same direction 152 as the air-flow taken into the air-inlet duct 110.

In some cases the center of the central wheel 305 can be open, e.g., to facilitate air flow communication to the spaces between the impeller blades 310. In some cases, such as illustrated in FIG. 3, there can be a shaft 330 passing through the center of the central wheel 305 that the impeller blades 310 rotate around. In such cases, there can be openings 340 around the shaft 330, e.g., to facilitate air flow communication to the spaces between the impeller blades 310.

As illustrated in FIG. 1, in some cases, to facilitate directing air flow in a desired direction 150, the motorized air-mover 125 (e.g., impeller) can be conically shaped. In order to maintain the desired gap 130, the cavity 120 can be configured to substantially match at least a portion of the shape of the air-mover 125. In some cases, for instance, the cavity 120 is configured to have a shape that matches at least a portion of the exterior shape of the air-mover 125 such that the gap 130 is present on all sides (e.g., side 170) of the motorized air-mover 125 except for sides (e.g., 172, 174) that are facing the air-inlet duct 110 or the air-outlet duct 115. For instance, when the air-mover 125 is conically-shaped then the cavity 120 can be configured to be conically-shaped, or when the air-mover 125 is disked-shaped or cylindrically shaped then the cavity can be configured to be disked-shaped or cylindrically shaped, respectively.

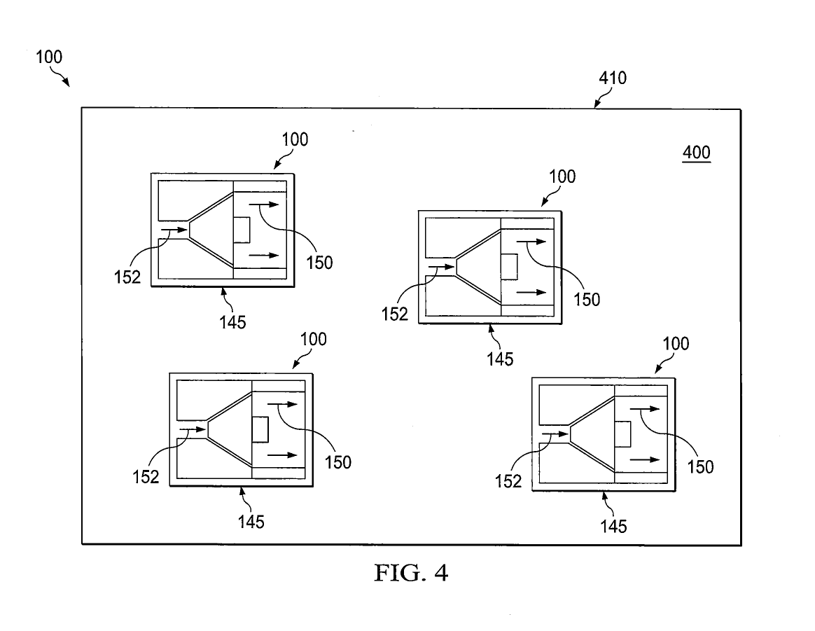

Another embodiment of the disclosure is an electronics apparatus. FIG. 4 presented a plan view of an example electronics apparatus 400 of the present disclosure which can include any of the example devices and component parts depicted in FIGS. 1-3. The apparatus 400 comprises an electronic circuit board 410 having one or more heat sources 145 thereon. In some cases the heat source includes one or more active devices (e.g., integrated circuit) or passive devices (e.g., resistors). The apparatus 400 also comprises one or more devices 100 located proximate to (e.g., in some cases, directly on) one of the heat source 145. Any of the embodiments of devices 100 discussed in the context of FIGS. 1-3 could be used in the apparatus 400.

As illustrated in FIG. 4, in some cases, to facilitate heat dissipation, each of the devices 100 can be configured to expel air from the air-outlet duct 115 (FIG. 1 or 2) in substantially a same direction 150 as the other devices 100. Similarly, in some cases, each of the each of the devices 100 can be configured to intake air from the air-inlet duct 110 (FIG. 1 or 2) substantially a same direction 152 as the other devices 100. In some cases, for each of the one or more devices 100, a direction 150 of air expelled from the air-outlet duct 115 of each device 110 is substantially the same as (e.g., a parallel to) a direction 152 of outside air-flow taken into the air-inlet duct 110 of the same device 100. Based on the present disclosure, one skilled in the art would appreciate that the directions 150, 152 of air expelled or air intake could be non-parallel or have other directions to facilitate further cooling of other components on the board 410.

Although the present disclosure has been described in detail, those skilled in the art should understand that they can make various changes, substitutions and alterations herein without departing from the scope of the invention.

What is claimed is:

1. A device, comprising:
a casing enclosing an air-inlet duct, air-outlet duct and a cavity located between the air-inlet duct and the air-outlet duct and in air-flow communication with the air-inlet duct and the air-outlet duct;
a motorized air-mover located in the cavity, the motorized air-mover configured to move air from the air-inlet duct to the air-outlet duct, wherein there is a gap between an outer-surface of the motorized air-mover and an interior wall of casing defining the cavity.

2. The device of claim 1, wherein the gap is configured such that a distance separating the outer-surface of the motorized air-mover and the interior wall is a gap value in a range of 10 to 1000 microns.

3. The device of claim 1, wherein the casing is configured such that a direction of air expelled from the air-outlet duct is in substantially a same direction of outside air-flow taken into the air-inlet duct.

4. The device of claim 1, wherein one or both of the air-inlet duct or cavity are surrounded by a high-thermal conductivity material.

5. The device of claim 1, wherein the high-thermal conductivity material is configured as a vapor chamber or a thermal siphon.

6. The device of claim 1, wherein the high-thermal conductivity material includes channels that allow the circulation of a single or two-phase fluid there-through.

7. The device of claim 1, wherein the motorized air-mover is configured as an impeller.

8. The device of claim 7, wherein blades of the impeller are configured to increase in height from a central location of the impeller to a perimeter of the impeller.

9. The device of claim 1, wherein the motorized air-mover is conically-shaped.

10. The device of claim 1, wherein the motorized air-mover is cylindrically shaped.

11. The device of claim 1, wherein the cavity is configured to have a shape that matches at least a portion of the exterior shape of the motorized air-mover such that the gap is present on all sides of the motorized air-mover except for sides that are facing the air-inlet duct or the air-outlet duct.

12. An electronics apparatus, comprising:
an electronic circuit board having one or more heat sources thereon;
one or more devices located proximate to one of the heat source, each of the devices including:
a casing enclosing an air-inlet duct, air-outlet duct and a cavity located between the air-inlet duct and the air-outlet duct and in air-flow communication with the air-inlet duct and the air-outlet duct;
a motorized air-mover located in the cavity, the motorized air-mover configured to move air from the air-inlet duct to the air-outlet duct, wherein there is a gap between an outer-surface of the motorized air-mover and an interior wall of casing defining the cavity.

13. The apparatus of claim 12, wherein each of a plurality of the devices is configured to expel air from the air-outlet duct in substantially a same direction as each other.

14. The apparatus of claim 12, wherein each of the devices is configured to intake air from the air-inlet duct substantially a same direction as each other.

15. The apparatus of claim 12, wherein for each of the one or more devices a direction of air expelled from the air-outlet duct is substantially the same as a direction of outside air-flow taken into the air-inlet duct.

16. The apparatus of claim 12, wherein the heat source includes one or more active devices.

17. The apparatus of claim 12, wherein the heat source includes one or more passive devices.

18. The apparatus of claim 12, wherein the gap is configured such that a distance separating the outer-surface of the motorized air-mover and the interior wall is a gap value in a range of 10 to 1000 microns.
